(19) United States
(12) Patent Application Publication
(10) Pub. No.: US 2009/0177594 A1
(43) Pub. Date: Jul. 9, 2009

(54) Method for rewarding water conservation and generating additional revenue for hotels

(76) Inventor: Edwrad Chuck Williams, JR., Macedonia, OH (US)

Correspondence Address: James A. Hudak, Esq., Suite #304, 29425 Chagrin Blvd., Cleveland, OH, 44122, US

(21) Appl. No.: 12/006,463

(22) Filed: Jan. 4, 2008

(51) Int. Cl. G01R 11/63

(52) U.S. Cl. 705/412

(57) ABSTRACT

A method for rewarding hotel guests for conserving water and for generating additional revenue for hotels is disclosed. A water flow control device that regulates the amount of water flowing through a shower head is installed between the shower head and the hot water supply line in each of the guest rooms in the hotel and is connected by a data line to a memory storage device for the hotel. The amount of water used in each guest room is monitored and data relating to water usage is collected and transmitted to the memory storage device. These data are then utilized by the hotel management to create incentives, i.e., perks and rewards, for those guests who have conserved water while showering.

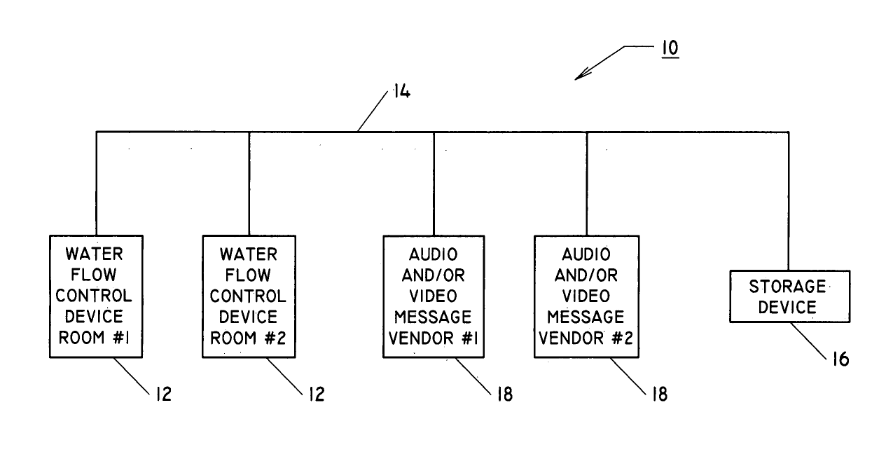

### TECHNICAL FIELD

The present invention relates, in general, to water conservation and, more particularly, to a method for rewarding individuals for conserving water and energy in a public facility, such as a hotel.

### BACKGROUND ART

Due to the relatively high cost of energy to heat water and the scarcity of water in certain geographic areas, various approaches have been utilized to attempt to reduce the costs of fuel to heat water and also to conserve the usage of water. Big users of heated water are hotels since most hotel guests take at least one shower every day. In addition, the guests who are showering are probably doing so at a relatively leisurely pace in order to relax. Thus the amount of heated water used in hotels for showering is substantial and the energy required to heat the water is significant. Some hotels may encourage guests to conserve water when showering by posting unobtrusive signs encouraging water conservation but there are no programs in hotels directed specifically to water conservation that would reward guests for conserving water and energy.

In view of the foregoing, it has become desirable to develop a method for monitoring water usage by hotel guests while showering and rewarding those guests who have conserved water and enabling hotels to receive incremental income from vendors and advertisers who can now market to a captured audience.

### SUMMARY OF THE INVENTION

The present invention solves the problems of water conservation by hotel guests while showering and other problems by providing a method for rewarding such guests for conserving water. The present invention utilizes a water flow control device incorporating a water limiting valve. The water flow control device regulates the amount of water flowing through a shower head and is installed between the shower head and the hot water supply line. The device can increase or decrease the flow of water through the shower head depending upon the position of the person with respect to the shower head. The devices are installed in each of the guest rooms in a hotel and are connected by a data line or via wireless or other connectivity technologies to a memory storage line in the hotel. The amount of water used in each guest room is monitored and data related to water usage is collected and transmitted to the memory storage device. The hotel management then utilizes these data for creating rewards, i.e., perks and rewards, for those guests who have conserved water showering. In order to encourage water conservation, audio and/or video messages can transmitted over the data line to the guest showering encouraging water conservation. These messages can include advertisements from vendors resulting in advertising revenue for the hotel.

### BRIEF DESCRIPTION OF THE DRAWINGS

The single FIGURE of the drawings is a block diagram of the system utilized by the present invention.

### DESCRIPTION OF THE PREFERRED EMBODIMENT

The present invention utilizes a water flow control device incorporating a water limiting valve such as that disclosed in U.S. Pat. No. 6,695,281 (Williams, Jr.). The water flow control device disclosed in the aforementioned patent regulates the amount of water flowing through a shower head. The device is interposed between the shower head and the water supply line and consists of a sensor and a solenoid that actuates and deactuates a water limiting valve connected in the water supply line. The device can increase or decrease the flow of water through the shower head depending upon the position of the person with respect to the shower head. In this manner, the amount of water used by a person when showering is conserved.

Referring now to the drawings, the single FIGURE of the drawings is a block diagram of the system 10 utilized by the present invention. A water flow control device 12, such as that disclosed in U.S. Pat. No. 6,695,281, is installed in each of the guest rooms in a hotel, or the like. The devices are connected by a data link 14 to a memory storage device 16 for the hotel. The amount of water used by each guest is monitored and data relating to shower water usage is collected and transmitted to the memory storage device 16. The hotel then utilizes these data for the purpose of creating marketing incentives, i.e., perks and rewards, for those guests who have conserved water when showering. These incentives or rewards can include a discount on the room rate, discounts on food or beverage service, etc. In order to encourage water conservation, audio and/or video messages 18 can be delivered to the person showering encouraging water conservation. These messages can be delivered at periodic intervals during the showering process. These messages can include advertisements from vendors to the “captured” audience, the person showering. In this manner, the hotel can receive a continual revenue stream from the advertisers.

From the foregoing, it is apparent that installation of a water flow control device 12, such as that described, in the guest rooms of a hotel, or the like, encourages water conservation and generates energy savings associated with the heating of the water. In addition, the monitoring of water usage by the hotel guests and the collection of water usage data and the usage of same for guest incentives or rewards further encourages water conservation. Furthermore, the use of voice message advertising to the “captured” audience, the guests while taking showers, provides a source of revenue from vendors. Such vendors could include toiletry suppliers, restaurants, entertainment venues, sightseeing attractions, etc., all of which would provide a source of revenue for the hotel. Thus, savings in the form of water conservation, energy conservation with respect to the heating of water and advertising revenue would accrue to the hotel while the hotel guest would receive rewards and incentives for conserving water.

Certain modifications and improvements will occur to those skilled in the art. It is understood that all such modifications and improvements have been deleted herein for the sake of conciseness and readability, but are properly within the scope of the following claims.

I claim:

1) A method of monitoring water usage and rewarding water users and enabling hotels to receive additional income from conserving water and water heating energy comprising the steps of:
a) Installing a water limiting valve on a shower head;
b) Monitoring the flow of water through said water limiting valve;
c) Collecting data as to the amount of water that flows through said water limiting valve in a period of time;
d) Transmitting said data regarding said amount of water flowing through said water limiting valve to a data storage device;
e) Comparing said data regarding said amount of water flowing through said water limiting valve to a predetermined value;
f) Determining whether said amount of water flowing through said water limiting valve is less than said predetermined value;
g) Providing an output when said amount of water flowing through said water limiting valve is less than said predetermined value; and
h) Determining a reward for said user when said amount of water flowing through said water limiting valve is less than said predetermined value.

2) The method as defined in claim 1 wherein said output is a document indicating that said amount of water flowing through said water limiting valve is less than said predetermined value.

3) The method as defined in claim 2 wherein said document indicates the difference between said amount of water flowing through said water limiting valve and said predetermined value.

4) The method as defined in claim 3 wherein said difference between said amount of water flowing through said water limiting valve and said predetermined value is utilized to determine said reward when said amount of water flowing through said water limiting valve is less than said predetermined value.

5) The method as defined in claim 1 further including video means to encourage the user to minimize said amount of water that flows through said water limiting valve.

6) The method as defined in claim 1 further including audio means to encourage the user to minimize said amount of water that flows through said water limiting valve.

7) The method as defined in claim 1 further including video means to promote third party vendors.

8) The method as defined in claim 1 further including audio means to promote third party vendors.
